(19) United States
(12) Patent Application Publication
(10) Pub. No.: US 2013/0120967 A1
(43) Pub. Date: May 16, 2013

(54) LIGHT EMITTING DIODE PACKAGE

(71) Applicant: Chao-Jung Liao, Taipei City (TW)

(72) Inventor: Chao-Jung Liao, Taipei City (TW)

(73) Assignee: EVERGREEN OPTRONICS INC., Taipei City (TW)

(21) Appl. No.: 13/323,808

(22) Filed: Dec. 12, 2011

(30) Foreign Application Priority Data
Nov. 14, 2011 (TW) 100141430

(51) Int. Cl. G09F 13/04; F21V 1/00; H01L 33/08

(52) U.S. Cl. 362/97.1; 257/88; 362/311.02; 257/E33.061

(57) ABSTRACT

A light emitting diode (LED) package including a transparent substrate, a transparent wiring layer, and at least one LED device is provided. The transparent wiring layer is disposed on the transparent substrate. The LED device is disposed on the transparent substrate and electrically connected to the transparent wiring layer.

### CROSS-REFERENCE TO RELATED APPLICATION

This application claims the priority benefit of Taiwan application serial no. 100141430, filed on Nov. 14, 2011. The entirety of the above-mentioned patent application is hereby incorporated by reference herein and made a part of this specification.

### BACKGROUND OF THE INVENTION

1. Field of the Invention

The invention generally relates to a light emitting diode (LED) package, and more particularly, to a light emitting diode package capable of emitting light toward various directions.

2. Description of Related Art

In a light emitting diode (LED) package, a group III-V element serves as the main material of a light emitting layer. By applying current to the light emitting layer, electrons and holes in the light emitting layer can be combined, and thereby the light emitting layer is allowed to emit light. Conventional LED packages emit light through heating or discharging, while the LED package herein emits cold light; therefore, the service life of the LED package is long, and no idling time is required. Besides, the LED package has advantages of fast response speed, small volume, low power consumption, low degree of pollution (no mercury contained), great reliability, adaptation of mass production, and so on. As a result, the LED package has been extensively applied in various fields.

Generally, a carrier substrate and a wiring layer of the LED package are often made of metal materials with high electrical conductivity and high coefficient of thermal conductivity. Notwithstanding said characteristics of high electrical conductivity and high coefficient of thermal conductivity, the carrier substrate and the wiring layer made of metal materials block light and do not allow light transmission. Hence, the conventional LED package can merely achieve the light emitting effect at one side of the carrier substrate.

### SUMMARY OF THE INVENTION

The invention is directed to a light emitting diode (LED) package capable of emitting light in various directions.

In the invention, an LED package including a transparent substrate, a transparent wiring layer, and at least one LED device is provided. The transparent wiring layer is disposed on the transparent substrate. The LED device is disposed on the transparent substrate and electrically connected to the transparent wiring layer.

In the invention, an illumination apparatus including a lampshade and said LED package is provided, and the LED package is disposed in the lampshade.

In the invention, a backlight module including said LED package and at least one light guiding device is provided, and the light guiding device is disposed on the LED package.

According to an embodiment of the invention, the LED package may further include a molding compound. The molding compound covers the LED device.

According to an embodiment of the invention, the LED package may further include a phosphor. The phosphor covers the LED device.

According to an embodiment of the invention, the phosphor is a distributed into the molding compound.

According to an embodiment of the invention, the LED package may further include a dam. The dam surrounds the molding compound.

According to an embodiment of the invention, a material of the dam includes silicone.

According to an embodiment of the invention, the at least one LED device refers to a plurality of LED devices, and wavelength bands of light beams emitted from at least two of the LED devices are different.

According to an embodiment of the invention, a light beam emitted from at least one of the LED devices has a wavelength ranging from 310 nm to 750 nm.

According to an embodiment of the invention, the LED package may further include a plurality of molding compounds. The molding compounds respectively cover the LED devices.

According to an embodiment of the invention, the LED package may further include a plurality of dams. The dams respectively surround the molding compounds.

According to an embodiment of the invention, the LED package may further include a plurality of phosphors. The phosphors are respectively distributed into the molding compounds.

According to an embodiment of the invention, at least two of the phosphors have different components.

According to an embodiment of the invention, a component of one of the phosphors is yellow phosphorus, red phosphorus, green phosphorus, or a combination thereof.

According to an embodiment of the invention, the transparent substrate has at least one groove, and the LED device is disposed in the groove.

According to an embodiment of the invention, the LED device is electrically connected to the transparent wiring layer through flip-chip bonding.

According to an embodiment of the invention, a coefficient of thermal conductivity of the transparent substrate is greater than 2 W/m·K.

According to an embodiment of the invention, a material of the transparent wiring layer includes antimony tin oxide (ATO), aluminum zinc oxide (AZO), or indium tin oxide (ITO).

Based on the above, the LED package described in the embodiments of the invention is equipped with the transparent substrate and the transparent wiring layer, and therefore light emitted from the LED device not only can be transmitted in a direction away from the transparent substrate but also can pass through the transparent substrate. Thereby, the LED package herein can emit light in various directions.

Several exemplary embodiments accompanied with figures are described in detail below to further explain the invention.

### BRIEF DESCRIPTION OF THE DRAWINGS

The accompanying drawings are included to provide a further understanding of the disclosure, and are incorporated in and constitute a part of this specification. The drawings illustrate exemplary embodiments of the invention and, together with the description, serve to explain the principles of the invention.

FIG. 1A is a schematic top view illustrating a light emitting diode (LED) package according to an embodiment of invention.

FIG. 1B is a schematic cross-sectional view taken along a line section I-I′ depicted in FIG. 1A.

FIG. 2A is a schematic top view illustrating an LED package according to another embodiment of invention.

FIG. 2B is a schematic cross-sectional view taken along a line section II-II′ depicted in FIG. 2A.

FIG. 3A is a schematic top view illustrating an LED package according to another embodiment of invention.

FIG. 3B is a schematic cross-sectional view taken along a line section III-III′ depicted in FIG. 3A.

FIG. 4 is a schematic cross-sectional view illustrating an LED package according to another embodiment of the invention.

FIG. 5 is a schematic cross-sectional view illustrating an LED package according to another embodiment of the invention.

FIG. 6 is a schematic view illustrating an illumination apparatus according to an embodiment of the invention.

FIG. 7 is a schematic view illustrating a backlight module according to an embodiment of the invention.

### DETAILED DESCRIPTION OF DISCLOSED EXEMPLARY EMBODIMENTS

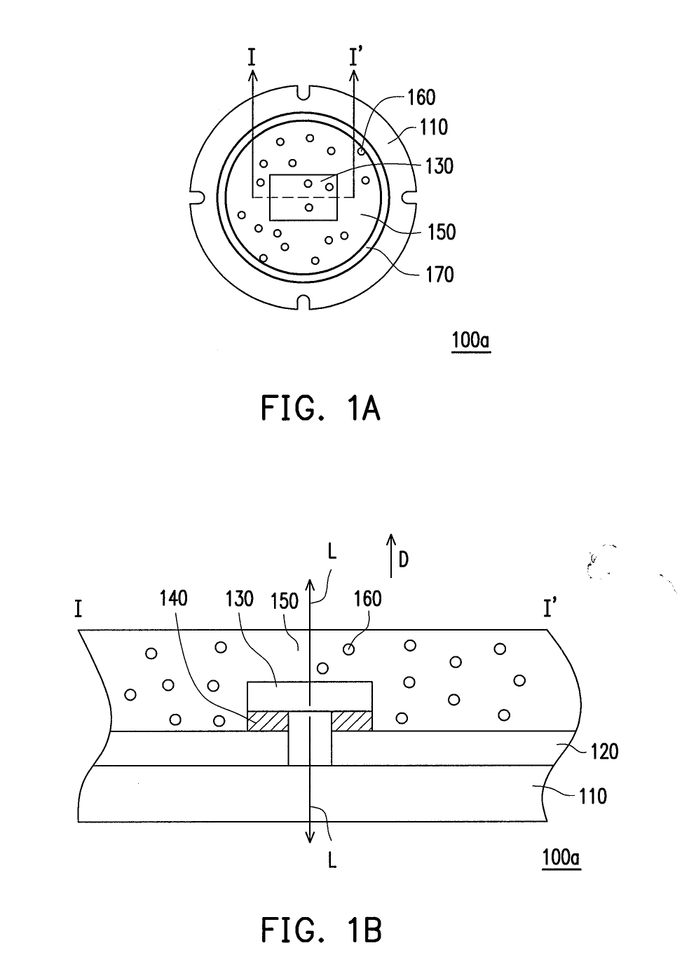

FIG. 1A is a schematic top view illustrating a light emitting diode (LED) package 100a according to an embodiment of invention. FIG. 1B is a schematic cross-sectional view taken along a line section I-I′ depicted in FIG. 1A. With reference to FIG. 1A and FIG. 1B, the LED package 100a includes a transparent substrate 110, a transparent wiring layer 120, and at least one LED device 130. The transparent wiring layer 120 is disposed on the transparent substrate 110. The LED device 130 is disposed on the transparent substrate 110 and electrically connected to the transparent wiring layer 120.

In the present embodiment, the substrate 110 may be a rigid transparent substrate or a flexible transparent substrate. The rigid transparent substrate is a glass substrate or a sapphire substrate, for instance, and the flexible transparent substrate is made of polyethylene terephthalate (PET) or polyvinyl chloride (PVC), for instance. As to the physical properties, the transparent substrate 110 is preferably characterized by great light transmission and high coefficient of thermal conductivity. To be more specific, in this embodiment, the light transmission rate of the transparent substrate 110 may be greater than 90%, and the coefficient of thermal conductivity may be greater than 2 W/m·K.

The transparent wiring layer 120 is disposed on the transparent substrate 110. According to this embodiment, the transparent wiring layer 120 is, for instance, made of antimony tin oxide (ATO). It should be mentioned that ATO is not only characterized by great electric conductivity and heat resistance but also characterized by low costs; therefore, in this embodiment, the manufacturing costs of the LED package 100a can be reduced when the transparent wiring layer 120 is made of ATO. However, this should not be construed as a limitation to the invention, and the transparent wiring layer can also be made of indium tin oxide (ITO), aluminum zinc oxide (AZO), or any other appropriate transparent conductive material according to other embodiments.

Note that the LED package 100a described in the present embodiment has the transparent substrate 110 and the transparent wiring layer 120, and therefore a light beam L emitted from the LED package 100a not only can be transmitted in a direction D away from the transparent substrate 110 but also can pass through the transparent substrate 110 and the transparent wiring layer 120. Thereby, the LED package 100a of this embodiment can emit light in various directions.

Besides, the LED package 100a of the present embodiment may further include a conductive bump 140 located between the LED device 130 and the transparent wiring layer 120. That is to say, the LED device 130 may be electrically connected to the transparent wiring layer 120 through flip-chip bonding in this embodiment. However, this should not be construed as a limitation to the invention, and the LED device 130 may be electrically connected to the transparent wiring layer 120 through wire bonding or in another appropriate manner according to other embodiments.

The LED package 100a of this embodiment may further include a molding compound 150. In the present embodiment, the molding compound 150 may cover the LED device 130 and may be made of a transparent material, e.g., epoxy resin or silicone. Here, the molding compound 150 serves to protect the LED device 130 and the conductive bump 140 from being affected by temperature and moisture in the surroundings because temperature and moisture may lead to a decrease in the service life of the LED device 130 and the conductive bump 140.

A phosphor 160 may be mixed into the molding compound 150 in this embodiment, so as to convert the light beam L emitted from the LED device 130 into another light beam with a different wavelength. For instance, in this embodiment, the light beam L emitted from the LED device 130 may be blue light with a wavelength band ranging from 450 nm to 520 nm, and the phosphor 160 may be red phosphorus. Through the red phosphorus, the blue light emitted from the LED device 130 can be converted into purple light. In another embodiment, the light beam L emitted from the LED device 130 may be the blue light with a wavelength band ranging from 450 nm to 520 nm, and the phosphor 160 may be yellow phosphorus. Through the yellow phosphorus, the blue light emitted from the LED device 130 can be converted into white light. Further, in still another embodiment, the light beam L emitted from the LED device 130 may be ultraviolet light with a wavelength band ranging from 310 nm to 400 nm, and the phosphor 160 may be yellow phosphorus. Similarly, through the yellow phosphorus, the ultraviolet light emitted from the LED device 130 can be converted into the white light. The light beam L emitted from the LED device 130 may be the blue light with a wavelength band ranging from 450 nm to 520 nm, and the phosphor 160 may be mixed by red phosphorus and green phosphorus. Through the red phosphorus and the green phosphorus, the blue light emitted from the LED device 130 can be converted into the white light.

Nevertheless, the invention should not be construed as limited to the embodiments set forth herein. In the present embodiment, the light beam L emitted from the LED device 130 may also be purple light with a wavelength band ranging from 400 nm to 450 nm, green light with a wavelength band ranging from 420 nm to 560 nm, yellow light with a wavelength band ranging from 560 nm to 600 nm, orange light with a wavelength band ranging from 600 nm to 625 nm, red light with a wavelength band ranging from 625 nm to 700 nm, or infrared light with a wavelength band ranging from 700 nm to 750 nm. Together with the use of proper phosphor, the desired color light or white light may be generated by converting the light beam L with various wavelength bands as described above.

In this embodiment, the molding compound 150 is in a liquid state with fluidity before it is solidified; thus, in order for the molding compound 150 not to be overflowed, which may further pose a negative impact on the optical uniformity (e.g., uniformity of color temperature) of the LED package 100a, the LED package 100a described in this embodiment may alternatively include a dam 170. Particularly, in the process of fabricating the LED package 100a, the dam 170 can be configured on the transparent substrate 110 and surround the LED device 130. The molding compound 150 is then introduced into the dam 170. Since the dam 170 can prevent the molding compound 150 from overflowing, the molding compound 150 and the phosphor 160 distributed into the molding compound 150 may evenly and levelly cover the LED device 130, so as to ensure that the optical uniformity (e.g., uniformity of color temperature) of the LED package 100a is satisfactory.

It should be mentioned that one LED device 130 and one phosphor 160 are exemplarily shown in FIG. 1A and FIG. 1B, while the number or the wavelength band of the LED device 130 and the number or the type of the phosphor 160 are not limited in the invention. In other embodiments, the LED package may include a plurality of LED devices with the same wavelength band or different wavelength bands. Together with the use of different phosphors, these LED devices with the same wavelength band or different wavelength bands can emit light with various wavelength bands. This will be discussed with reference to the following embodiment.

In the previous embodiment and the following embodiments, same reference numbers are used to represent same or similar elements, and repetitive explanation is omitted hereinafter. For a detailed description of the omitted section, reference can be found in the previous embodiment of the invention; therefore, no further explanation is provided in the following embodiments.

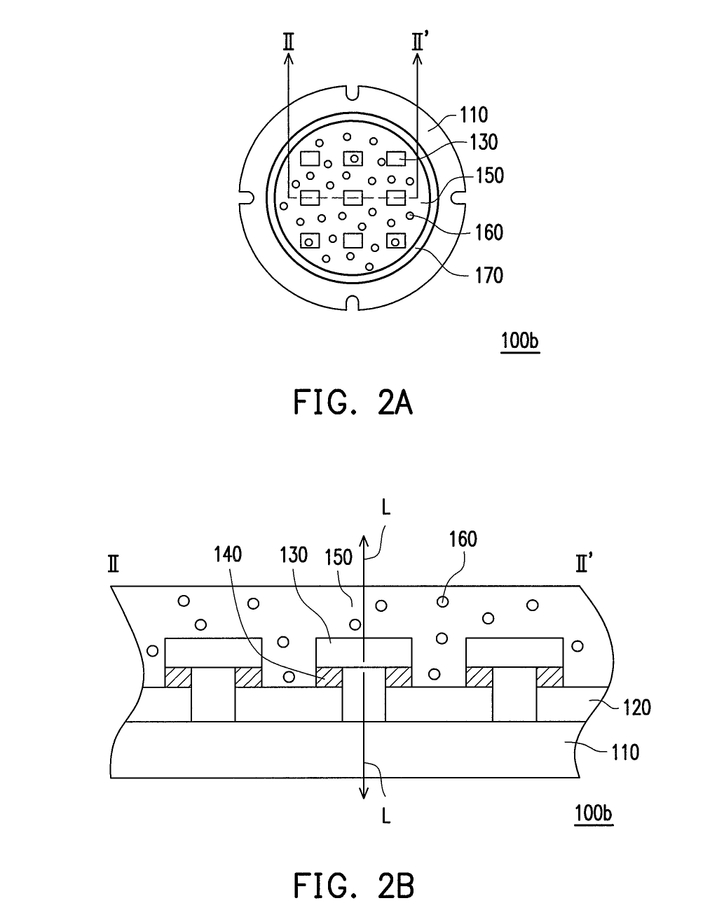

FIG. 2A is a schematic top view illustrating an LED package 100b according to another embodiment of invention, and FIG. 2B is a schematic cross-sectional view taken along a line section II-II′ depicted in FIG. 2A. With reference to FIG. 2A and FIG. 2B, the LED package 100b of the present embodiment is similar to the LED package 100a of the previous embodiment. Specifically, the LED package 100b includes a transparent substrate 110, a transparent wiring layer 120, a conductive bump 140, a molding compound 150, a phosphor 160, and a dam 170.

Different from the embodiment shown in FIG. 1A, this embodiment discloses that the LED package 100b includes a plurality of LED devices 130 disposed on the transparent substrate 110. The molding compound 150 completely cover the LED devices 130. The phosphor 160 is respectively distributed into the molding compound 150. Compared to the LED package 100a having one LED device 130 and one phosphor 160 in the previous embodiment, the LED package 100b having plural LED devices 130 and the phosphor 160 in this embodiment is allowed to have higher brightness. The molding compound 150 consecutively covers the LED devices 130 in this embodiment, which should not be construed as a limitation to the invention. In other embodiments, the molding compound 150 may cover the LED devices 130 in a different way. This will be discussed with reference to the following embodiment.

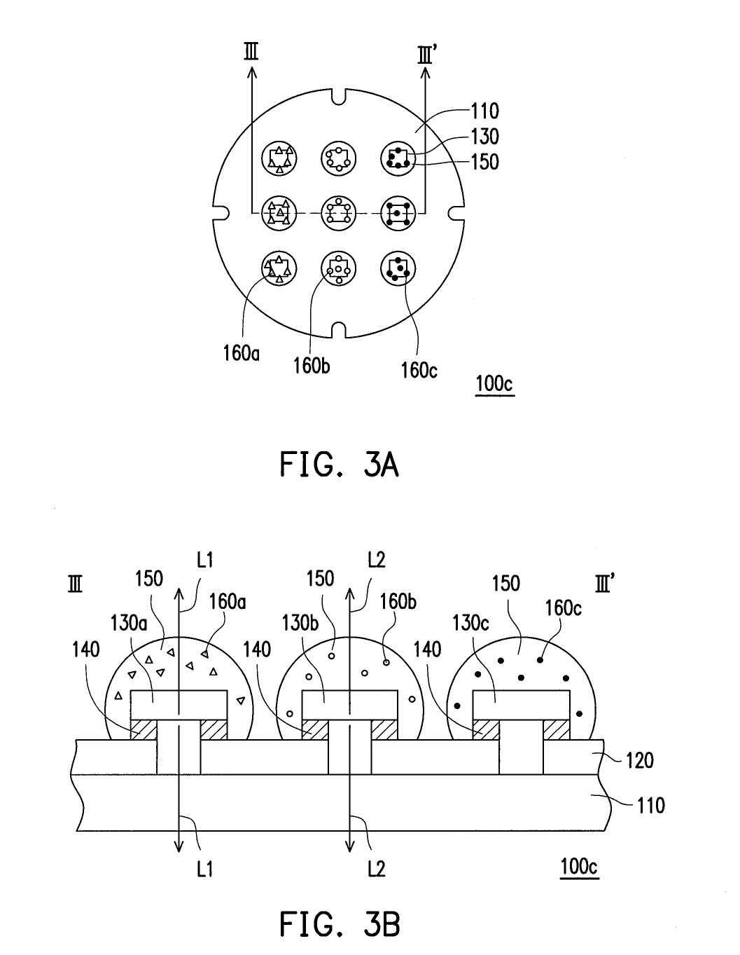

FIG. 3A is a schematic top view illustrating an LED package 100c according to another embodiment of invention, and FIG. 3B is a schematic cross-sectional view taken along a line section depicted in FIG. 3A. With reference to FIG. 3A and FIG. 3B, the LED package 100c includes a transparent substrate 110, a transparent wiring layer 120, a plurality of LED devices 130, a conductive bump 140, a plurality of molding compounds 150, and a plurality of phosphors 160. The LED package 100c described in this embodiment is similar to the LED package 100b in the previous embodiment, while the molding compounds 150 do not consecutively cover the LED devices 130 but are respectively dispensed to cover the LED devices 130.

To be more specific, the LED devices 130 are, for instance, a first LED device 130a, a second LED device 130b, and a third LED device 130c, and the phosphors 160 are, for instance, a first phosphor 160a, a second phosphor 160b, and a third phosphor 160c. According to this embodiment, the molding compounds 150 respectively cover the first LED device 130a, the second LED device 130b, and the third LED device 130c. It should be mentioned that the LED devices 130 are covered by a small amount of the molding compounds 150, and thus the surface tension can preclude the molding compounds 150 from overflowing. As such, the dam is not required in this embodiment, and the molding compounds 150 are still not in physical contact with one another. From another aspect, the required amount of the molding compounds 150 and the phosphors 160 can be reduced through dispensing the molding compounds 150 on the LED devices 130, thus leading to reduction of materials and manufacturing costs.

In this embodiment, a light beam L1 emitted from the first LED device 130a may have a wavelength band ranging from 450 nm to 520 nm, and the first phosphor 160a is made of yellow phosphorus, for instance. Together with the use of the first phosphor 160a, the first LED device 130a can emit white light. A light beam L2 emitted from the second LED device 130b has a wavelength band ranging from 450 nm to 520 nm, and the second phosphor 160b is made of red phosphorus, for instance. Together with the use of the second phosphor 160b, the second LED device 130b can emit purple light. A light beam L3 emitted from the third LED device 130c has a wavelength band ranging from 310 nm to 400 nm, and the third phosphor 160c is made of yellow phosphorus, for instance. Together with the use of the third phosphor 160c, the third LED device 130c can emit white light. Namely, in the present embodiment, light with different colors, white light, or a combination of color light and white light can be generated by the LED devices 130a, 130b, and 130c with different wavelength bands and different phosphors 160a, 160b, and 160c. It is worth pointing out that the types and the combined usage of the LED devices and phosphors set forth above are to enable those with ordinary skill in the art to implement the invention and are not intended for limiting the invention. People skilled in the art are able to employ different LED devices as well as different phosphors based on product requirements.

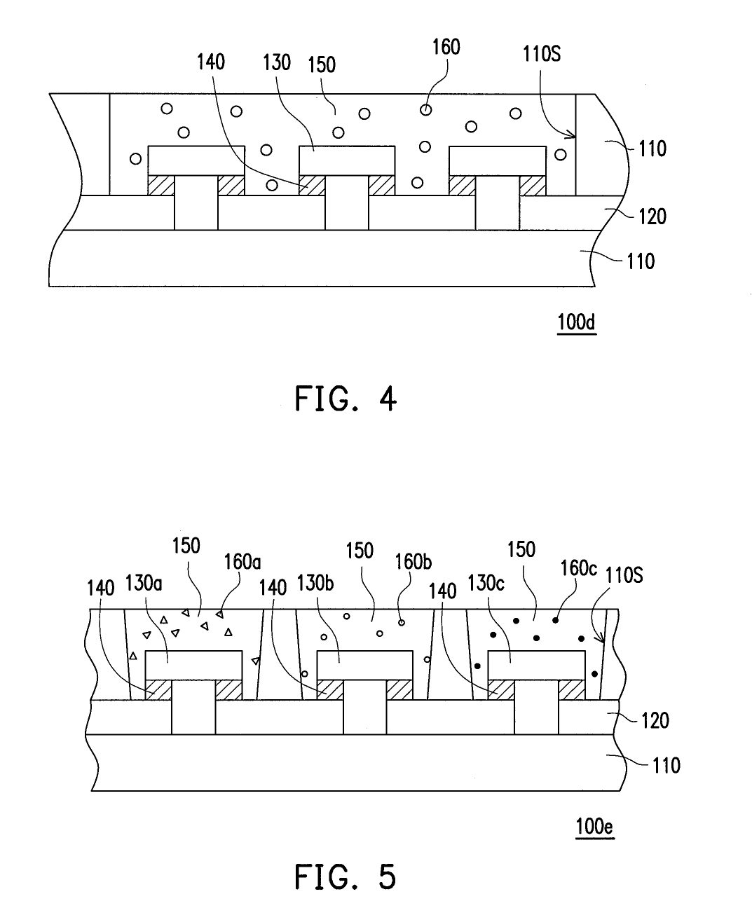

FIG. 4 is a schematic cross-sectional view illustrating an LED package 100d according to another embodiment of the invention. Similar to the LED package 100b illustrated in FIG. 2B, the LED package 100d of the present embodiment shown in FIG. 4 includes a plurality of LED devices 130, and the molding compound 150 consecutively covers all of the LED devices 130. The difference between the LED package 100d and the LED package 100b lies in that the transparent substrate 110 of this embodiment has a groove 110S, and the groove 1105 is functioned in a similar way as that of the dam 170 shown in FIG. 2A, i.e., preventing the molding compound 150 from overflowing. The LED devices 130 are disposed in the groove 1105. The molding compound 150 and the phosphor 160 cover the LED devices 130 and are disposed in the groove 1105. As such, when the molding compound 150 and the phosphor 160 are introduced, the molding compound 150 can be prevented from overflowing even though the LED package 100d is not equipped with the dam, and thereby the LED package 100d can be characterized by favorable optical properties.

However, the number of the groove 110S or whether to configure the groove 1105 is not limited in the invention, and in other embodiments the transparent substrate 100 may have a plurality of grooves 110S to respectively carry the LED devices 130. For instance, please refer to FIG. 5, which is a schematic cross-sectional view illustrating an LED package 100e according to another embodiment of the invention. As indicated in FIG. 5, the transparent substrate 100 of this embodiment has a plurality of grooves 110S, and each of the grooves 1105 has one of the LED devices 130 therein. Similar to the LED device 100c depicted in FIG. 3B, the wavelength bands of the LED devices 130 herein are either the same or different, and so are the types of the phosphors 160. In this embodiment, the LED package 100e can also emit light with various colors, white light, or a combination thereof.

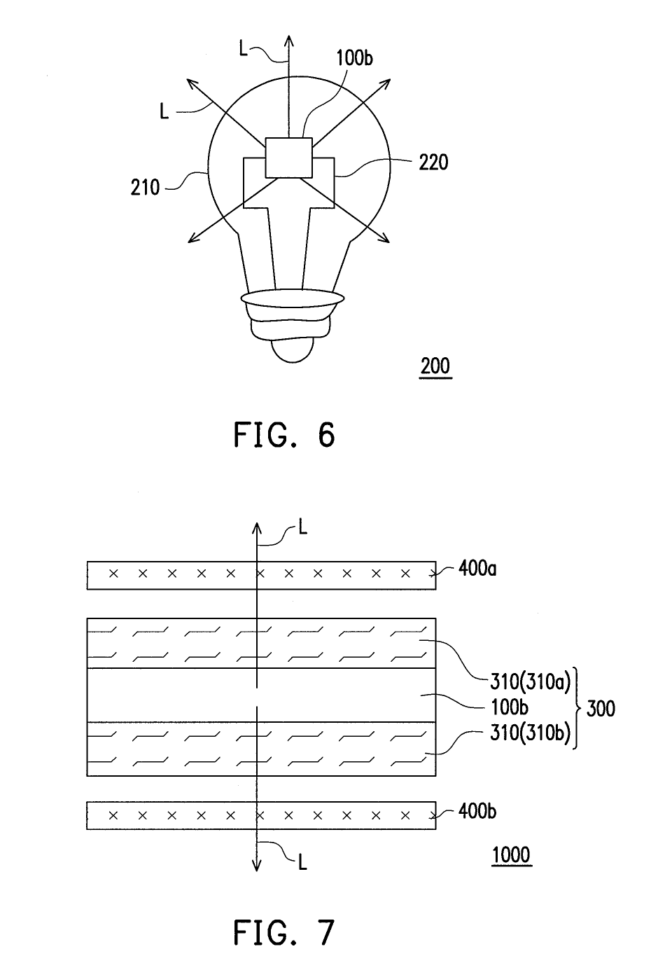

A variety of applications of the LED package can be developed in this invention, and an exemplary embodiment is provided hereinafter. FIG. 6 is a schematic view illustrating an illumination apparatus 200 according to an embodiment of the invention. As indicated in FIG. 6, the illumination apparatus 200 includes a lampshade 210 and the LED package 100b described in the previous embodiment of the invention. The illumination apparatus 200 further includes a holder 220 according to this embodiment. The LED package 100b is located inside the lampshade 210 and electrically connected to wires (not shown) on the holder 220. Voltages are input to the LED package 100b through the wires on the holder 220, so as to emit the light beam L. Note that the LED package 100b of this invention can emit light in various directions and thus can replace the light source in a conventional light bulb, i.e., the illumination apparatus 200 having the LED package 100b is capable of emitting light toward various directions. This should however not be construed as a limitation to the invention, and the aforesaid LED package 100a, 100c, 100d, or 100e can also serve as the light source and is applicable to the illumination apparatus 200.

FIG. 7 is a schematic view illustrating a backlight module 300 according to an embodiment of the invention. As indicated in FIG. 7, the backlight module 300 of this embodiment includes the LED package 100b and at least one light guiding device 310. The light guiding device 310 is disposed on the LED package 100b. Note that the LED package 100b of this invention can emit light in various directions, and thus the backlight module 300 having the LED package 100b is applicable to a double-sided display 1000. Particularly, the light guiding devices 310a and 310b and the transmissive display panels 400a and 400b can be respectively disposed at two sides of the LED package 100b. Light beams L emitted from both sides of the LED package 100b serve as the light sources of the transmissive display panels 400a and 400b, respectively, so as to allow the double-sided display 1000 to achieve the double-sided display effect. This should however not be construed as a limitation to the invention, and the aforesaid LED package 100a, 100c, 100d, or 100e can also serve as the light source and is applicable to the backlight module 300.

In addition, the LED packages 100a˜100e described in the embodiments of the invention can act as embellishment of buildings. For instance, the LED packages 100a˜100e described in the embodiments of the invention can be embedded into the windows of buildings. Due to the fact that the LED packages 100a˜100e can emit light with different colors toward various directions, the LED packages 100a˜100e not only can decorate the exterior of buildings but also can serve as the light sources required by people in the buildings.

In light of the foregoing, the carrier substrate or the conductive wiring layer is made of metal according to the related art, and the resultant LED package can merely emit light from one side. By contrast, the LED package described in the embodiments of the invention is equipped with the transparent substrate and the transparent wiring layer that allow light transmission, and therefore the light beam emitted from the LED device can pass through the transparent substrate. Since the light beam from the LED device is not blocked by the substrate, the LED package herein is capable of emitting light in various directions.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A light emitting diode package comprising:
a transparent substrate;
a transparent wiring layer disposed on the transparent substrate; and
at least one light emitting diode device disposed on the transparent substrate and electrically connected to the transparent wiring layer.

2. The light emitting diode package as recited in claim 1, further comprising a molding compound covering the light emitting diode device.

3. The light emitting diode package as recited in claim 2, further comprising a phosphor covering the light emitting diode device.

4. The light emitting diode package as recited in claim 3, wherein the phosphor is a distributed into the molding compound.

5. The light emitting diode package as recited in claim 1, further comprising a dam surrounding the molding compound.

6. The light emitting diode package as recited in claim 5, wherein a material of the dam comprises silicone.

7. The light emitting diode package as recited in claim 1, wherein the at least one light emitting diode device is a plurality of light emitting diode devices, and wavelength bands of light beams emitted from at least two of the light emitting diode devices are different.

8. The light emitting diode package as recited in claim 7, wherein a light beam emitted from at least one of the light emitting diode devices has a wavelength ranging from 310 nm to 750 nm.

9. The light emitting diode package as recited in claim 1, further comprising a plurality of molding compounds, the at least one light emitting diode device being a plurality of light emitting diode devices, the molding compounds respectively covering the light emitting diode devices.

10. The light emitting diode package as recited in claim 9, further comprising a plurality of dams respectively surrounding the molding compounds.

11. The light emitting diode package as recited in claim 9, further comprising a plurality of phosphors respectively distributed into the molding compounds.

12. The light emitting diode package as recited in claim 11, wherein at least two of the phosphors have different components.

13. The light emitting diode package as recited in claim 11, wherein a component of one of the phosphors is yellow phosphorus, red phosphorus, green phosphorus, or a combination thereof.

14. The light emitting diode package as recited in claim 1, wherein the transparent substrate has at least one groove, and the at least one light emitting diode device is disposed in the at least one groove.

15. The light emitting diode package as recited in claim 1, wherein the at least one light emitting diode device is electrically connected to the transparent wiring layer through flip-chip bonding.

16. The light emitting diode package as recited in claim 1, wherein a coefficient of thermal conductivity of the transparent substrate is greater than 2 W/m·K.

17. The light emitting diode package as recited in claim 1, wherein a material of the transparent wiring layer comprises antimony tin oxide(ATO), aluminum zinc oxide(AZO), or indium tin oxide(ITO).

18. An illumination apparatus comprising:
a lampshade; and
the light emitting diode package comprising:
a transparent substrate;
a transparent wiring layer disposed on the transparent substrate; and
at least one light emitting diode device disposed on the transparent substrate and electrically connected to the transparent wiring layer, wherein the light emitting diode package is disposed in the lampshade.

19. A backlight module comprising:
the light emitting diode package comprising:
a transparent substrate;
a transparent wiring layer disposed on the transparent substrate; and
at least one light emitting diode device disposed on the transparent substrate and electrically connected to the transparent wiring layer;
at least one light guiding device disposed on the light emitting diode package.
